(19) United States
(12) Patent Application Publication
(10) Pub. No.: US 2006/0017159 A1
(43) Pub. Date: Jan. 26, 2006

(54) Semiconductor device and method of manufacturing a semiconductor device

(75) Inventor: Shuji Kamata, Hyogo-ken (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Kabushiki Kaisha Toshiba, Tokyo (JP)

(21) Appl. No.: 11/185,777

(22) Filed: Jul. 21, 2005

(30) Foreign Application Priority Data
Jul. 22, 2004 (JP) 2004-213696

(51) Int. Cl. H01L 23/48; H01L 23/52

(52) U.S. Cl. 257/737; 257/784; 257/750

(57) ABSTRACT

According to an aspect of the present invention, there is provided a semiconductor device including a lead frame, a semiconductor chip, a back surface opposed to a main surface of the semiconductor chip disposed on the lead frame, a first electrode formed on the main surface of the semiconductor chip, the first electrode being composed of Al as a main component, a wiring, one end portion of the wiring being connected to the first electrode, and the other end portion of the wiring being connected to a lead terminal of the lead frame, a second electrode formed on the first electrode, the second electrode selectively formed except an area at least connected the one end portion of the wiring, and being composed of Cu as a main component.

### CROSS REFERENCE TO RELATED APPLICATION

This application is based upon and claims the benefit of priority from the prior Japanese Patent Application No. JP2004-213696, filed on Jul. 22, 2004, the entire contents of which are incorporated herein by reference.

### FIELD OF THE INVENTION

The present invention relates to a semiconductor device and a method of manufacturing a semiconductor device, and in particular, a semiconductor device including an optimum structure to tightly connect a wiring to an electrode formed on a surface of a semiconductor chip and a method of manufacturing the semiconductor device.

### DESCRIPTION OF THE BACKGROUND

Conventionally, in processing steps of manufacturing a semiconductor device connected between a semiconductor chip and a package, wiring bonding is applied to the connection to a connection pad in the semiconductor chip.

Recently, Cu having higher conductivity than conductivity of Al has been utilized as a wiring material accompanying with highly developing a semiconductor device. For example, a layered electrode having a Cu layer on an Al layer has been utilized in a power MOS transistor to reduce power loss caused by the electrode resistance accompanying with high power in operation.

A method of heating Cu in a reduction atmosphere, for example, is performed in connecting Al or Au wire to a connect pad of the Cu electrode. However, coupling strength between the wire and the connect pad is not easily obtained, because Cu has difficulty to being formed an alloy with Al or Au.

On the other hand, it is well-known that a connection pad made of a metal which is easily formed an alloy with Al or Au is formed on the Cu electrode and the connection conductor is connected to the connection pad.

In a connect method between a Cu electrode and a connection conductor disclosed on Japanese Patent Publication (Kokai) No. H11-191575, a Sn plating layer having a thickness of 0.3-1.2 μm is formed on an electrode of a circuit substrate, for example a Cu electrode on a print wiring plate. Next, an Au bump formed on an electrode of a semiconductor chip and the Sn plating layer is pressed in heating below Sn melting point so as to form an Au—Sn alloy layer by solid phase reaction. As a result, a semiconductor chip is mounted on the print wiring plate by a flip chip method.

Furthermore, a semiconductor device including an Au bump through a Ni barrier layer formed on a Cu electrode is well-known.

In a semiconductor device disclosed on Japanese Patent Publication (Kokai) No. 2000-91369, a Cu film having a thickness of 1 μm formed by using non-electroplating and Ni barrier layer having a thickness of 0.5-5 μm formed by using non-electroplating is stacked on a connection pad of a Cu electrode. An Au bump formed through a Ni barrier layer is also well-known as a conventional method.

However, as Sn or Ni is formed on a Cu electrode by using non-electroplating in the methods, processing steps of manufacturing a semiconductor device are increased. Moreover, a cost of manufacturing the semiconductor device becomes higher with a thickness of the plating layer.

### SUMMARY OF THE INVENTION

According to an aspect of the invention, there is provided a semiconductor device, including a lead frame, a semiconductor chip, a back surface opposed to a main surface of the semiconductor chip disposed on the lead frame, a first electrode formed on the main surface of the semiconductor chip, the first electrode being composed of Al as a main component, a wiring, one end portion of the wiring being connected to the first electrode, and the other end portion of the wiring being connected to a lead terminal of the lead frame, a second electrode formed on the first electrode, the second electrode selectively formed except an area at least connected the one end portion of the wiring, and being composed of Cu as a main component.

Further, another aspect of the invention, there is provided a semiconductor device, including a lead frame, a semiconductor chip, a main surface of the semiconductor chip disposed on the lead frame, a first electrode formed on the main surface of the semiconductor chip, the first electrode being composed of Al as a main component, a protrusion-like wiring, one end portion of the protrusion-like wiring being connected to the first electrode, and the other end portion of the protrusion-like wiring being connected to a lead terminal of the lead frame, a second electrode formed on the first electrode, the second electrode selectively formed except an area at least connected the one end portion of the protrusion-like wiring, and being composed of Cu as a main component.

Further, another aspect of the invention, there is provided a method of manufacturing a semiconductor device, including preparing a semiconductor chip, forming a first electrode being composed of Al as a main component on the semiconductor chip, selectively forming a mask film on the first electrode, forming a second electrode being composed of Cu as a main component on the first electrode using the mask film as a mask, removing the mask film, sticking the semiconductor chip on a lead frame, connecting one end portion of a connection conductor to a connection pad exposed a surface of the first electrode, connecting the other end portion of the connection conductor to a lead terminal in the lead frame.

### BRIEF DESCRIPTION OF THE DRAWINGS

FIG. 1 is a block schematic diagram showing a semiconductor device according to a first embodiment of the present invention, FIG. 1A is a partially cutaway plan view showing the semiconductor device and FIG. 1B is an enlarged cross-sectional view showing along line A-A of FIG. 1A;

FIG. 2 is a block schematic diagram showing a semiconductor chip according to the first embodiment of the present invention, FIG. 2A is a plan view showing the semiconductor chip, FIG. 2B is an enlarged cross-sectional view showing along line B-B of FIG. 2A and FIG. 2C is an enlarged cross-sectional view showing along line C-C of FIG. 2A;

FIG. 3 is a characteristic diagram showing resistivity of a layered electrode having a Cu electrode stacked on an Al electrode according to the first embodiment of the present invention;

FIG. 4 is a cross-sectional view showing a method of manufacturing the layered electrode in the semiconductor chip and a connection pad according to the first embodiment of the present invention;

FIG. 5 is a characteristic diagram showing adhesion strength of a connection conductor formed on the connection pad according to the first embodiment of the present invention;

FIG. 6 is a block schematic diagram showing a semiconductor device according to a second embodiment of the present invention, FIG. 6A is a partially cutaway plan view showing the semiconductor device and FIG. 6B is an enlarged cross-sectional view showing along line D-D of FIG. 6A;

FIG. 7 is a block schematic diagram showing a semiconductor chip according to a third embodiment of the present invention, FIG. 7A is a plan view showing the semiconductor chip, FIG. 7B is an enlarged cross-sectional view showing along line E-E of FIG. 7A and FIG. 7C is an enlarged cross-sectional view showing a main portion of FIG. 7B.

### DETAILED DESCRIPTION OF THE INVENTION

Embodiments of the present invention will be described hereinafter in detail with reference to the drawings mentioned above.

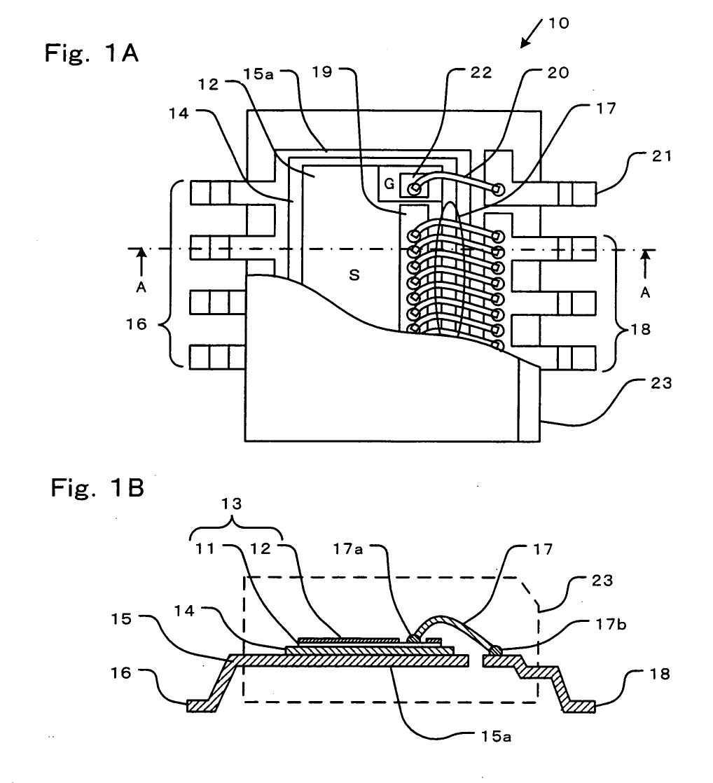

First, a semiconductor device according to a first embodiment of the present invention is explained in detail with reference to FIG. 1-5.

FIG. 1 is a block schematic diagram showing a semiconductor device according to a first embodiment of the present invention. FIG. 1A is a partially cutaway plan view showing the semiconductor device. FIG. 1B is an enlarged cross-sectional view showing along line A-A of FIG. 1A.

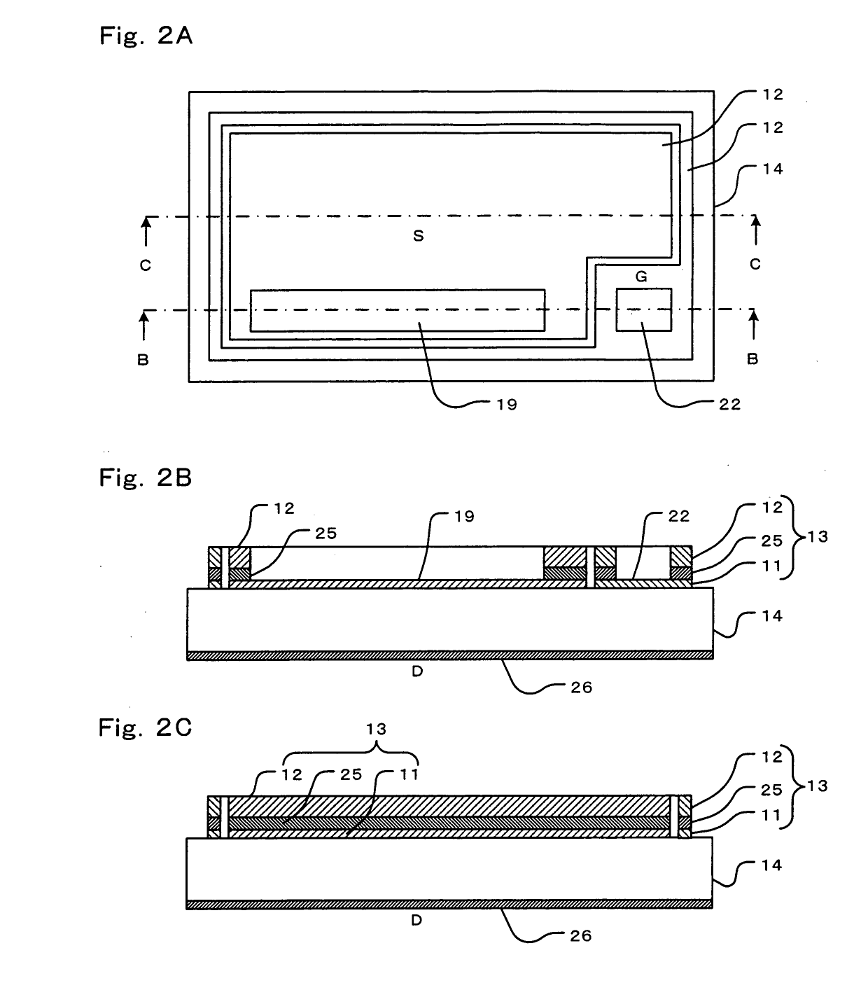

FIG. 2 is a block schematic diagram showing a semiconductor chip according to the first embodiment of the present invention. FIG. 2A is a plan view showing the semiconductor chip. FIG. 2B is an enlarged cross-sectional view showing along line B-B of FIG. 2A and FIG. 2C is an enlarged cross-sectional view showing along line C-C of FIG. 2A.

As shown in FIG. 1, a semiconductor device 10 showing the first embodiment includes a semiconductor chip 14 housed in a small outline package (SOP) with 8 pins. A layered electrode 13 having a Cu electrode 12 stacked on an Al electrode 11 is located on a surface of the semiconductor chip 14.

The semiconductor chip 14 is an N-channel vertical MISFET, such as a power MOSFET having a plurality of layered electrodes 13, a gate electrode G and a source electrode S on the front surface, and single electrode, such as a drain electrode D (not illustrated) on the back surface.

A side of the drain electrode D in the semiconductor chip 14 is turned to bottom and the semiconductor chip 14 is displaced on a lead frame 15 formed of Ni or solder-plating Cu. The drain electrode D is firmly adhered to an island portion 15a on the lead frame 15 by a conductive adhesion tape and is connected to a plurality of lead terminals 16.

The source electrode S is connected to a plurality of lead terminals 18 through a plurality of connection conductors 17. One end portion 17a of a plurality of the connection conductors 17 is connected to a connection pad 19 exposed the Al electrode 11 which is a part of the source electrode S. The other end portion 17b of a plurality of the connection conductors 17 is connected to a plurality of lead terminals 18. Similarly, the gate electrode G is connected to a lead terminal 22a through a conductor 20.

An end portion of the connection conductor 20 is connected to a connection pad 22 exposed the Al electrode 11 which is a part of the gate electrode G and the other end portion of the connection conductor 20 is connected to a lead terminal 21. The semiconductor chip 14 is molded by a resin 23. As a result, SOP-type of the semiconductor device 10 is constructed.

As shown in FIG. 2, the semiconductor chip 14 has the source electrode S in the center region of a top surface, the gate electrode G in the periphery region of the top surface and the drain electrode D all over a bottom surface. The source electrode S is a rectangular feature cut in a corner. The source electrode S and the gate electrode G have the layered electrode 13 having the Cu electrode 12 stacked on the Al electrode 11. For example, a thickness of the Cu electrode 12 is 5-10 μm and a thickness of the Al electrode 11 is 2-6 μm. A Ni inter layer 25 having such as a thickness of 1-5 μm, formed between the Al electrode 11 and the Cu electrode 12, so as to improve adhesion between the Al electrode 11 and the Cu electrode 12. An Al electrode 26 having such as a thickness of 2-6 μm is formed as the drain electrode D. The connection pads 19, 22 exposed the Al electrode 11 is formed as the source electrode S and a part of the gate electrode G.

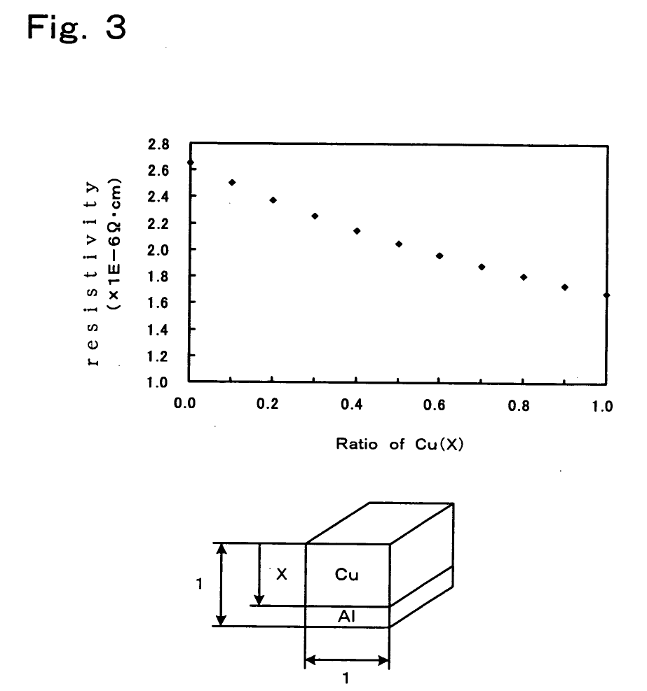

The electrode resistance of the layered electrode 13 having the Cu electrode 12 stacked on the Al electrode 11 is explained by a resistance connected the Al electrode 11 and the Cu electrode 12 in parallel. Accordingly, the electrode resistance has a resistance value according to the thicknesses of the Al electrode 11 and the Cu electrode 12. Namely, as shown in FIG. 3, a resistivity range of the layered electrode 13 is obtained from Al resistivity of 2.65E-6 Ω·cm to Cu resistivity of 1.67E-6 Ω·cm according to a ratio X of the Cu electrode 12.

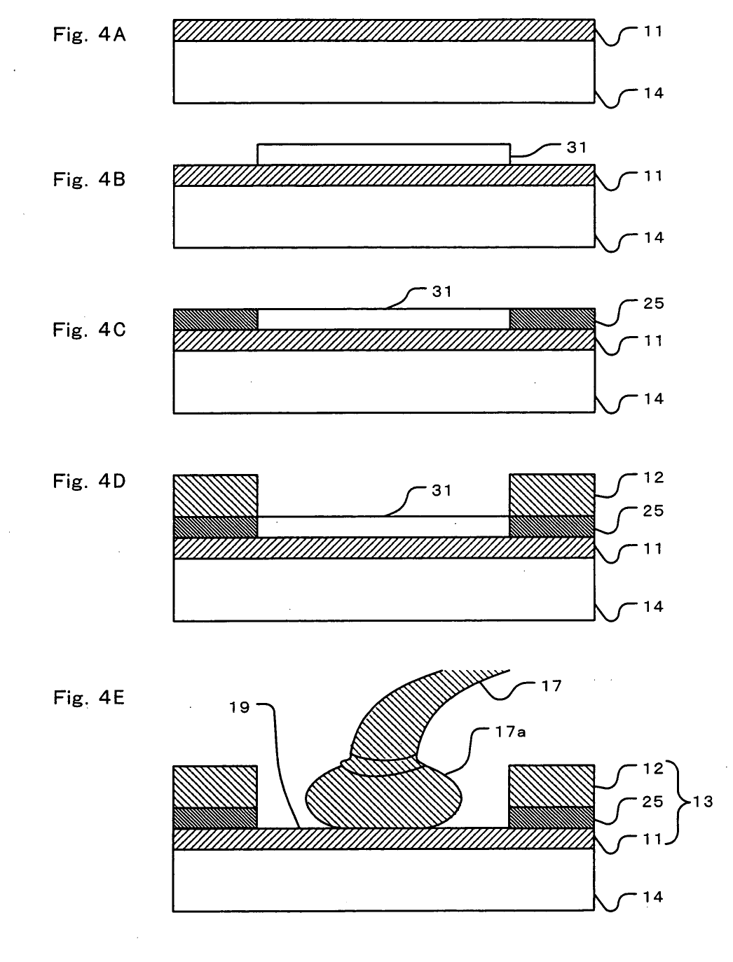

Next, a method of fabricating the semiconductor device 10 is explained in detail. FIG. 4 is a cross-sectional view showing a fabrication method of the layered electrode in the semiconductor chip and a connection pad according to the first embodiment.

First, as shown in FIG. 4A, the Al electrode 11 having such as a thickness of 2-6 μm is formed on the semiconductor chip 14 by using sputtering technique. A resist film 31 having such as a thickness of 1-2 μm is formed at a position disposed the connection pad 19, as shown in FIG. 4B.

Furthermore, as shown in FIG. 4C, the Ni inter layer 25 having such as a thickness of 1-5 μm is selectively formed on the Al electrode 11 by non-electroplating technique using a resist film 31 as a mask. In the process mentioned above, the sample is immersed in a Ni plating solution. Next, as shown in FIG. 4D, the Cu electrode 12 having such as the thickness of 5˜10 μm is selectively formed on the Ni inter layer 25 by non-electroplating technique using a resist film 31 as a mask. In the process mentioned above, the sample is immersed in a Cu plating solution.

As shown in FIG. 4E, by removing the resist film 31, the layered electrode 13 having the Cu electrode 12 stacked on the Al electrode 11 through the Ni inter layer 25 is formed and the connection pad 19 exposed the Al electrode 11 of the layered electrode 13 is obtained. One of the end portions 17a of the connection conductor 17 is connected to the connection pad 19. Similarly, the layered electrode 13 of a gate and the connection pad 22 are formed.

The semiconductor chip 14 is adhered to an island portion 15a of the lead frame 15 by a conductive adhesion tape. Successively, the connection pad 19 of the source electrode S and the connection pad 22 of the gate electrode G are connected to the lead terminals 18, 21 by the connection conductors 17, 20, such as an Au wire. Moreover, the whole semiconductor device manufactured by the processing steps described above is molded by the resin 23, so as to complete as the semiconductor device 10, as shown in FIG. 1.

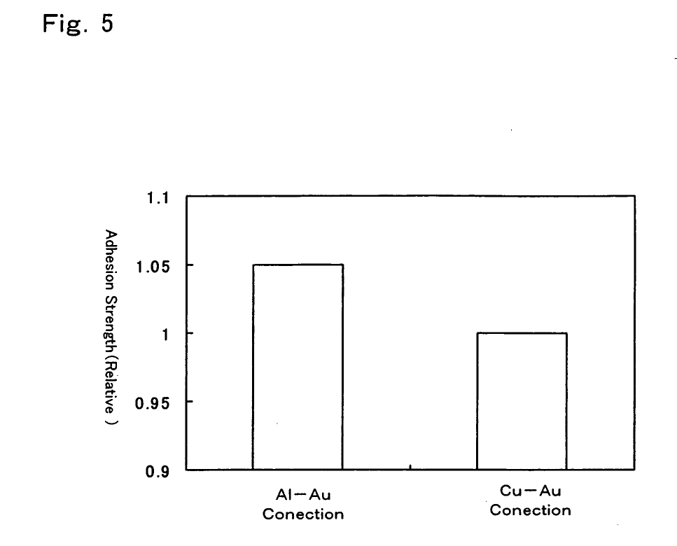

As mentioned above, by forming the connection pads 19, 22 exposed the Al electrode 11 in a part of the layered electrode 13 having the Cu electrode 12 stacked on the Al electrode 11, the connection conductor can be adhered strongly to the layered electrode 13. FIG. 5 shows comparison with the adhesion strength between Al connection pads 19, 22 and the Au wire and the adhesion strength between the Cu electrode and the Au wire. The adhesion strength on Al—Au connection is improved nearly 5% for the adhesion strength on Cu—Au connection.

As explained above, the semiconductor device according to the first embodiment, as the connection pad exposed the Al electrode in a part of the layered electrode having the Cu electrode 12 stacked on the Al electrode 11 is disposed, the connection conductor having a material contained no Cu at least on the surface can be strongly connected to a wiring. As a result, a semiconductor device with sufficient connection reliability is obtained and a highly reliable semiconductor device can be provided.

In the embodiment, the Cu electrode is formed by the non-electroplating technique; however, vacuum evaporation technique, sputtering technique and another technique also may be used within the limits from which the film thickness is obtained. In those case, the Ni inter layer may be omitted.

Furthermore, the embodiments describe the case that both the source electrode S and the gate electrode G are the layered electrodes. However, as an electrical current in the gate is nearly zero, other electrodes, such as the Al electrode expect the layered electrode also may be used within the limits in which the semiconductor device is normally operated.

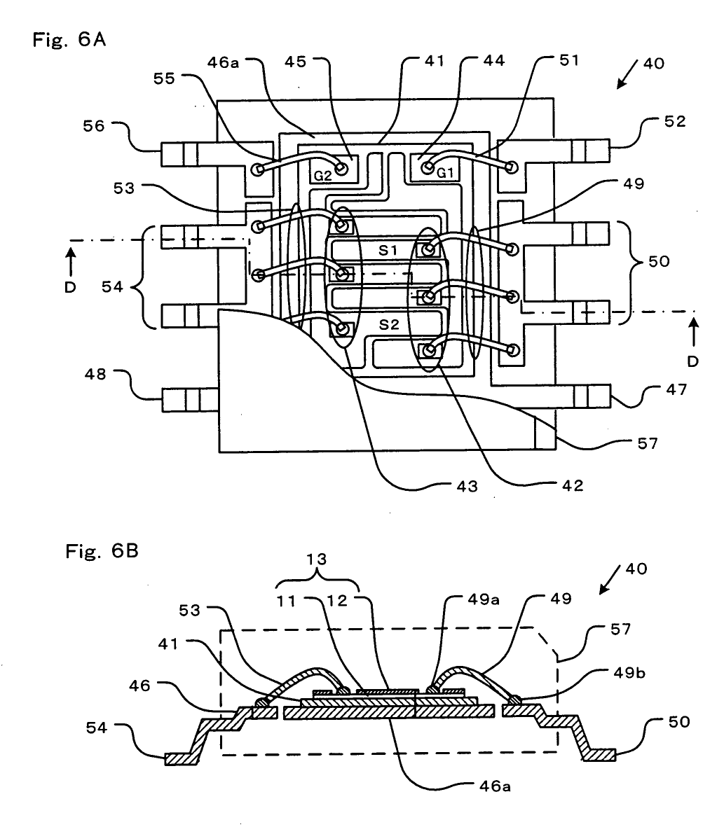

FIG. 6 is a block schematic diagram showing a semiconductor device according to a second embodiment of the present invention. FIG. 6A is a partially cutaway plan view showing the semiconductor device. FIG. 6B is an enlarged cross-sectional view showing along line D-D of FIG. 6A.

In the second embodiment, a portion of a same composition as the first embodiment is attached the same number and explanation of the portion of the same composition is omitted.

The second embodiment has a different point from the first embodiment as mentioned below. A resin is coated on a substrate so as to bury a solder bump; a semiconductor component is successively disposed on a substrate. A semiconductor chip integrated two power MOS transistors including a layered electrode having a Cu electrode stacked on an Al electrode is housed in small outline package.

As shown in FIG. 6, a semiconductor chip 41 arranged in a semiconductor device 40 in this embodiment includes source electrodes S1, S2 having cutaway corners opposed to a central portion in the surface of the semiconductor chip 41 and shaped like teeth of a comb, gate electrodes G1, G2 surrounding periphery of source electrodes S1, S2 and a common drain electrode D (not illustrated) formed in a whole back surface. Connection pads 42, 43 exposed the Al electrode 11 are formed in a foot portion of the teeth of a comb in the source electrodes S1, S2. Connection pads 44, 45 in the gate electrodes G1, G2 are formed in an area of the teeth of a comb in the source electrodes S1, S2.

The drain electrode D side of the semiconductor chip 41 is turned to bottom and the semiconductor chip 41 is displaced on a lead frame 46 made of Ni or solder-plating Cu. The drain electrode D is firmly adhered to an island portion 46a on the lead frame 46 by a conductive adhesion tape and is connected to a plurality of lead terminals 47, 48.

The source electrode S1 is connected to a plurality of lead terminals 50 through a plurality of connection conductors 49, such as Au wires. One end portion 49a of a plurality of the connection conductors 49 is connected to the connection pad 42 exposed the Al electrode 11, the other end portion 49b of a plurality of the connection conductor 49 is connected to a plurality of a lead terminal 50.

The gate electrode G1 is connected to a lead terminal 52 through a connection conductor 51. One end portion of the connection conductor 51 is connected to the connection pad 21 exposed the Al electrode 11 in the one end portion of the gate electrode G1, the other end portion of the connection conductor 51 is connected to the lead terminal 52. The source electrode S2 is connected to a plurality of the lead terminal 54 through a plurality of the connection conductor 53. The gate electrode G2 is connected to a lead terminal 56 through the connection conductor 55. The semiconductor device 40 including the semiconductor chip 14 et al. mentioned above is molded by a resin 57 and is completed as a SOP type semiconductor device.

Accordingly, connection pads 42-45 partially exposed the Al electrode 11 in the layered electrode 13 having the Cu electrode 12 stacked on the Al electrode 11 provides firmly coupling between the layered electrode 13 and the connection conductor.

As mentioned above, in the semiconductor device 40 according to the second embodiment 2, the connection pads 42-45 is disposed on the semiconductor chip 41 integrated two power MOS transistors exposed the Al electrode 11 in the layered electrode 13 having the Cu electrode stacked on the Al electrode 11. As a result, a small-type semiconductor device having sufficient coupling strength can be provided.

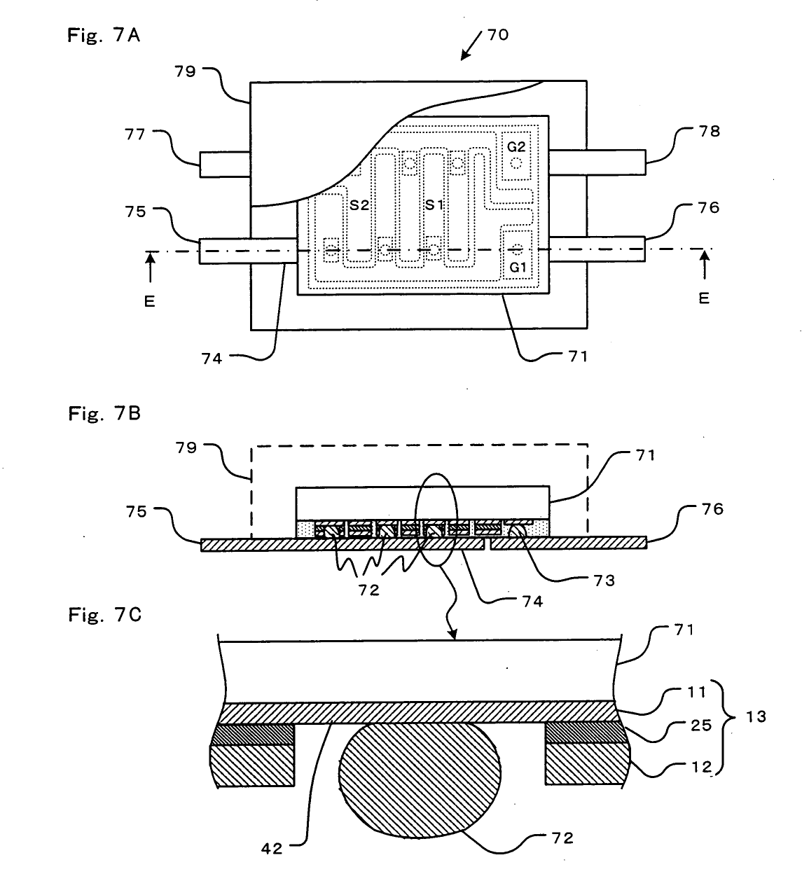

FIG. 7 is a block schematic diagram of a semiconductor device according to a third embodiment of the present invention. FIG. 7A is a partially cutaway plan view showing the semiconductor device. FIG. 7B is an enlarged cross-sectional view showing along line D-D of FIG. 7A. FIG. 7C is an enlarged cross-sectional view showing a main portion in FIG. 7B.

In the third embodiment, a portion of a same composition as the first embodiment is attached the same number and explanation of the portion of the same composition is omitted.

The third embodiment has a different point from the first embodiment as mentioned below. A metal bump is formed on a connection pad exposed an Al electrode of a semiconductor chip integrated two power MOS transistors including a layered electrode having a Cu electrode stacked on an Al electrode and is connected to a lead frame as a flip chip.

As shown in FIG. 7, a semiconductor chip 71 in a semiconductor device 70 in this embodiment includes a metal bump 72 on the connection pad 42 of the source electrode S1 and a metal bump (not illustrated) on the connection pad 43 of the source electrode S2.

Furthermore, the semiconductor chip 71 includes a metal bump 73 on the gate electrode G1 of the connection pad 44 and a metal bump (not illustrated) on the connection pad 45 of the gate electrode G2.

The metal bumps 72, 73 are an Au bump, for example. In processing steps of the Au bump, an Au ball is formed at a head of a capillary by using a bonding machine; subsequently the Au ball is applied to ultrasonic waves so as to bond on the connection pad where the Au ball is heating. Moreover, the Au ball on the connection pad is pressed so as to form an Au bump by stud bump technique.

The semiconductor chip 71 is disposed on the lead frame 74 made of Ni or Cu plated solder while a side of the source electrode S1, S2 and the gate electrode G1, G2 of the semiconductor chip 71 becomes downward. The source electrode S1 is connected to a lead terminal 75 through a plurality of the metal bumps 72 as a flip chip. The gate electrode G1 is connected to a lead terminal 76 through the Au bump 73 as a flip chip. The source electrode S2 is connected to a lead terminal 77 through a plurality of the Au bumps (not illustrated) as a flip chip. The gate electrode G1 is connected to a lead terminal 78 through the Au bumps (not illustrated) as a flip chip.

The semiconductor device 70 including the semiconductor chip 14 et al. mentioned above is molded by a resin 79 and is completed as a SOP-type semiconductor device.

Accordingly, the connection pads partially exposed the Al electrode 11 in the layered electrode 13 having the Cu electrode 12 stacked on the Al electrode 11 provides firmly coupling between the layered electrode 13 and the connection conductor.

As mentioned above, in the semiconductor device 70 according to the third embodiment, the connection pads is disposed on the semiconductor chip 71 integrated two power MOS transistors exposed the Al electrode 11 in the layered electrode 13 having the Cu electrode 12 stacked on the Al electrode 11. As a result, a small-type semiconductor device having sufficient coupling strength can be provided.

Other embodiments of the present invention will be apparent to those skilled in the art from consideration of the specification and practice of the invention disclosed herein. It is intended that the specification and example embodiments be considered as exemplary only, with a true scope and spirit of the invention being indicated by the claims that follow. The invention can be carried out by being variously modified within a range not deviated from the gist of the invention.

For example, a semiconductor chip may be connected to connection pads on a printed wiring substrate as a flip chip. Furthermore, the connection pads of the printed wiring substrate may be partially exposed the Al electrode in the layered electrode having the Cu electrode stacked on the Al electrode.

What is claimed is:

1. A semiconductor device, comprising:
a lead frame;
a semiconductor chip, a back surface opposed to a main surface of the semiconductor chip disposed on the lead frame;
a first electrode formed on the main surface of the semiconductor chip, the first electrode being composed of Al as a main component;
a wiring, one end portion of the wiring being connected to the first electrode, and the other end portion of the wiring being connected to a lead terminal of the lead frame;
a second electrode formed on the first electrode, the second electrode selectively formed except an area at least connected the one end portion of the wiring, and being composed of Cu as a main component.

2. The semiconductor device according to claim 1, wherein an area exposed the first electrode in a layered electrode having the second electrode stacked on the first electrode is a connection pad.

3. The semiconductor device according to claim 1, wherein the wiring is composed of Al or Au as a main component.

4. The semiconductor device according to claim 1, further comprising an inter layer mainly composed of Ni between the first electrode and the second electrode.

5. The semiconductor device according to claim 1, wherein a plurality of the semiconductor chips are disposed on the lead frame.

6. The semiconductor device according to claim 1, wherein the semiconductor chip includes a power semiconductor device.

7. The semiconductor device according to claim 6 wherein a gate electrode and a drain electrode of the power semiconductor device is formed on the semiconductor chip.

8. A semiconductor device, comprising:
a lead frame;
a semiconductor chip, a main surface of the semiconductor chip disposed on the lead frame;
a first electrode formed on the main surface of the semiconductor chip, the first electrode being composed of Al as a main component;
a protrusion-like wiring, one end portion of the protrusion-like wiring being connected to the first electrode, and the other end portion of the protrusion-like wiring being connected to a lead terminal of the lead frame;
a second electrode formed on the first electrode, the second electrode selectively formed except an area at least connected the one end portion of the protrusion-like wiring, and being composed of Cu as a main component.

9. The semiconductor device according to claim 8, wherein an area exposed the first electrode in a layered electrode having the second electrode stacked on the first electrode is a connection pad.

10. The semiconductor device according to claim 8, wherein the protrusion-like wiring is composed of Al or Au as a main component.

11. The semiconductor device according to claim 8, further comprising an inter layer mainly composed of Ni between the first electrode and the second electrode.

12. The semiconductor device according to claim 8, wherein a plurality of the semiconductor chips are disposed on the lead frame.

13. The semiconductor device according to claim 8, wherein the semiconductor chip includes a power semiconductor device.

14. The semiconductor device according to claim 13, wherein a gate electrode and a drain electrode of the power semiconductor device is formed on the semiconductor chip.

15. A method of manufacturing a semiconductor device, comprising:
preparing a semiconductor chip;
forming a first electrode being composed of Al as a main component on the semiconductor chip;
selectively forming a mask film on the first electrode;
forming a second electrode being composed of Cu as a main component on the first electrode using the mask film as a mask;
removing the mask film;
sticking the semiconductor chip on a lead frame;
connecting one end portion of a connection conductor to a connection pad exposed a surface of the first electrode;
connecting the other end portion of the connection conductor to a lead terminal in the lead frame;

16. The method of manufacturing the semiconductor device according to claim 15, further comprising forming an inter layer between the first electrode and the second electrode.

17. The method of manufacturing the semiconductor device according to claim 15, wherein the second electrode is formed by using non-electrolytic plating.

18. The method of manufacturing the semiconductor device according to claim 15, wherein the connection conductor has a protrusion-like shape.
